(19) United States
(12) Patent Application Publication
(10) Pub. No.: US 2025/0113548 A1
(43) Pub. Date: Apr. 3, 2025

(54) CARBON NANOTUBE DEVICES

(71) Applicant: Texas Instruments Incorporated, Dallas, TX (US)

(72) Inventors: Luigi Colombo, Dallas, TX (US); Baher S. Haroun, Allen, TX (US)

(73) Assignee: Texas Instruments Incorporated, Dallas, TX (US)

(21) Appl. No.: 18/479,025

(22) Filed: Sep. 30, 2023

(51) Int. Cl. H01L 29/786; H01L 21/02; H01L 29/06; H01L 29/66; H01L 29/775

(52) U.S. Cl. CPC H10D 30/6757; H01L 21/02527; H10D 30/01; H10D 30/43; H10D 62/121; H10D 62/8303

(57) ABSTRACT

A method includes forming, on a dielectric layer of an integrated circuit, a first layer of a first material, forming, on the first layer, a second layer of a second material, and patterning the second layer to expose the first layer. Via the patterned second layer, the exposed first layer is etched to form protrusion structures of the first layer and the second layer and grooves between adjacent ones of the protrusion structures. The method also includes forming a graphitic carbon layer on at least part of the second layer of the protrusion structures, and depositing carbon nanotubes into the grooves between the adjacent ones of the protrusion structures.

### BACKGROUND

Carbon nanotubes are cylindrical molecules made up of one or more layers of carbon atoms. A single-walled carbon nanotube having a single atom tube wall can be less than one nanometer in diameter. A multi-walled carbon nanotube can include multiple concentrically linked nanotubes with a diameter of from between a few nanometers to a hundred nanometers. Carbon nanotube lengths range from a few nanometers to millimeters. Carbon nanotubes can have electrical properties, such as high thermal and electrical conductivity, which make them an attractive candidate for use in photonic and electronic devices, such as light sources and detectors, and transistors.

### SUMMARY

In one example, a method includes forming, on a dielectric layer of an integrated circuit, a first layer of a first material, forming, on the first layer, a second layer of a second material, and patterning the second layer to expose the first layer. Via the patterned second layer, the exposed first layer is etched to form protrusion structures of the first layer and the second layer and undercut grooves between adjacent ones of the protrusion structures. The first layer of each protrusion structure has a first width, the second layer of each protrusion structure has a second width, and the second width is greater than the first width. The method also includes depositing carbon nanotubes into the undercut grooves between the adjacent ones of the protrusion structures.

In another example, a method includes forming, on a dielectric layer of an integrated circuit, a first layer of a first material, forming, on the first layer, a second layer of a second material, and patterning the second layer to expose the first layer. Via the patterned second layer, the exposed first layer is etched to form protrusion structures of the first layer and the second layer and grooves between adjacent ones of the protrusion structures. The method also includes forming a graphitic carbon layer on at least part of the second layer of the protrusion structures, and depositing carbon nanotubes into the grooves between the adjacent ones of the protrusion structures. The method can yet further include removing the protrusion structures, by etching to leave rows of aligned carbon nanotubes on the surface of the dielectric.

In a further example, a transistor includes a source, a drain, and a first and second arrays of carbon nanotubes. The first array of carbon nanotubes has a first width, a first end connected to the source, and a second end connected to the drain. The second array of carbon nanotubes is adjacent to and spaced apart from the first array of carbon nanotubes by a first spacing. The first width is greater than the first spacing.

### BRIEF DESCRIPTION OF THE DRAWINGS

FIG. 1 is a flow diagram for an example method of providing carbon nanotubes on an integrated circuit.

FIGS. 2, 3, 4, 5, 6, 7, 8, 9, 10, and 11 are schematics illustrating example operations of the method of FIG. 1.

FIG. 12 is a flow diagram for an example method of fabricating a transistor with carbon nanotubes deposited using the method of FIG. 1.

FIGS. 13, 14, 15, 16, 17, 18, and 19 are schematics illustrating example operations of the method of FIG. 12.

FIG. 20 is a schematic illustrating a transistor with carbon nanotubes and a top gate fabricated according to an example of the method of FIG. 12.

FIG. 21 is a schematic illustrating a transistor with carbon nanotubes and a global back gate fabricated according to an example of the method of FIG. 12.

### DETAILED DESCRIPTION

An electronic device, such as a field-effect transistor (FET), can include carbon nanotubes electrically connected between two current terminals of the FET (e.g., source and drain) to provide a current conducting channel between the current terminals. Both the number of carbon nanotubes between the current terminals, and the alignment of the carbon nanotubes with respect to the current terminals, can influence resistance of the current channel formed by the carbon nanotubes. Specifically, with more carbon nanotubes positioned within a footprint of the transistor, the current channel formed by carbon nanotubes can carry more current, and the resistance of the current channel can be reduced. Also, with the carbon nanotubes more aligned with a longitudinal axis of the FET, which can provide a shortest path between the current terminals, the distance travelled by the current between the current terminals can be reduced/minimized, which can further reduce the resistance of the current channel.

Example techniques to be described herein can increase the number of carbon nanotubes deposited between the current terminals of a FET while improving the alignment of the carbon nanotubes with the longitudinal axis of the FET. Specifically, protrusion structures extending between the current terminals of the FET are formed on a dielectric layer. Each protrusion structure can include a second layer and a first layer (or a link layer), where the first layer is between the second layer and the dielectric layer. The second layer can have a first width, the first layer can have a second width, with the first width larger than the second width. The second layer of adjacent protrusion structures can be spaced apart by a first distance, and the first layer of adjacent protrusion structures can be spaced apart by a second distance longer than the first distance.

In some examples, the first width of a second layer, and the first distance between the second layer of adjacent protrusion structure, can be the same and reflect a minimum line width of a lithography process used to pattern and etch the second layer. The etching of the second layer can be performed using an isotropic etchant. After the second layer is patterned and the first layer is exposed, the exposed first layer can be over-etched using an anisotropic etchant, or by an isotropic etchant but with extended etching time, to create an undercut groove below the patterned second layer. In some examples, the undercut can reach 50% of the first width of the second layer of each protrusion structure. The undercut can increase the width of the groove between the first layer of adjacent protrusion structures enabling carbon nanotube spreading and thus higher surface coverage.

In some examples, the second layer of the protrusion structures can be coated with a graphitic carbon layer, which has a low adhesion to carbon nanotubes. The graphitic carbon layer can also serve as an etch-stop layer for the second layer during the etching of the bottom layer, to facilitate the over-etching/undercut of the exposed first layer. Further, the graphitic carbon layer(s) can be grown on the top metal layer to have a well-defined thickness, e.g., less than 1 nm, so that the first distance between the second layer of adjacent protrusion structures (which is reduced by the thickness of the graphitic carbon layer) can also be well defined, and the first distance can be substantially uniform across the protrusion structures. After forming the protrusion structures, carbon nanotubes in solution can be deposited (e.g., dipped, spun, swiped) into the grooves between the protrusion structures and the undercut regions. The space between the patterned second layer of the protrusion structures can act as guides to direct and align the carbon nanotubes into the undercut groove below the second layer to form a film. The graphitic carbon coated on the second layer can prevent the carbon nanotubes from adhering onto the second layer and facilitate the sliding of the carbon nanotubes into the grooves.

The alignment of the carbon nanotubes can be set by the shear rate as well as the first distance between the second layer of adjacent protrusion structures. After the carbon nanotubes are deposited into and form films in the grooves and undercut regions, the protrusion structures can be removed. With such arrangements, the width of each carbon nanotube film in the FET can be larger than the spacing between the top metal lines or the spacing between adjacent carbon nanotube films.

By setting the first distance to a minimum line width, and by coating the second layer with a graphitic carbon layer(s) having a well-controlled thickness, the first distance between the second layer of adjacent protrusion structures can be minimized and can be substantially uniform across the protrusion structures. Such arrangements can maximize (or at least increase) the alignment of the carbon nanotubes in the FET.

Further, with the techniques described herein to create the undercut grooves, the width of the grooves (the second distance between the first layer of adjacent protrusion structures) can increase above the first distance between the second layer of adjacent protrusion structures, which can increase the density of the carbon nanotubes. Compared with a case where no undercut groove is formed and the groove width is the same as the first distance, the described techniques can increase the number of carbon nanotubes deposited between adjacent protrusion structures while improving (or at least maintaining) the alignment of the carbon nanotubes.

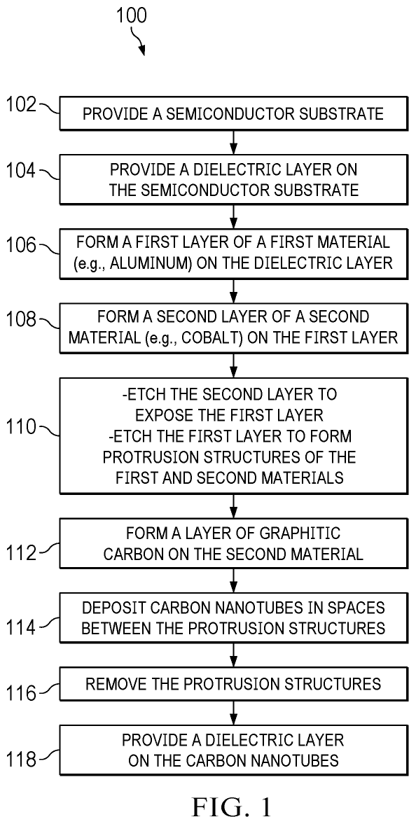

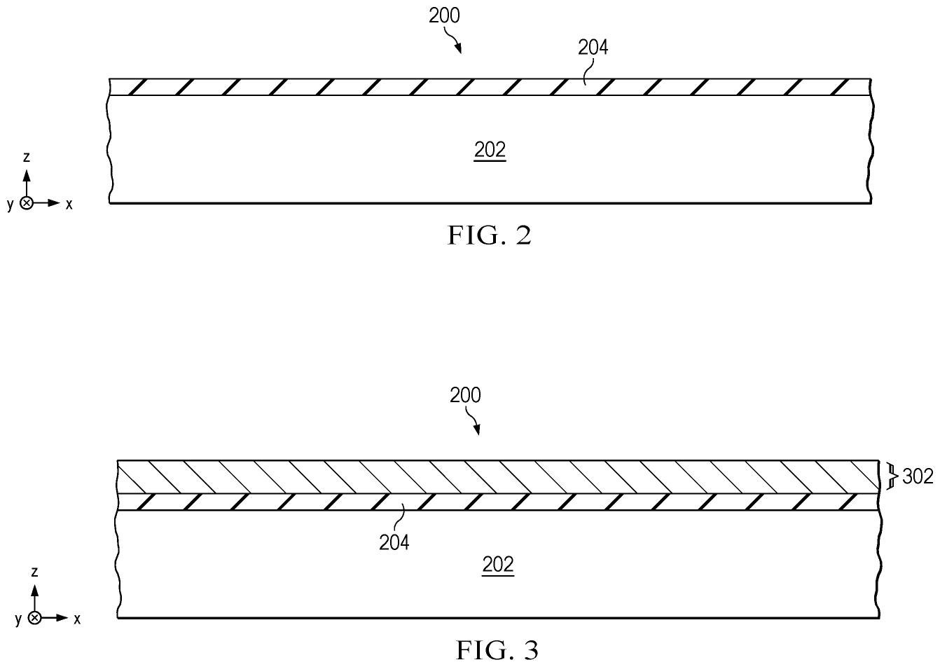

FIG. 1 is a flow diagram for an example method 100 of providing carbon nanotubes on an integrated circuit (IC). Though depicted sequentially as a matter of convenience, at least some of the actions shown can be performed in a different order and/or performed in parallel. Additionally, some implementations may perform only some of the actions shown. FIGS. 2-11 are schematics that illustrate the state of IC in example operations of the method 100.

In block 102, a material 202 is provided to form an integrated circuit 200. FIG. 2 illustrates a cross sectional diagram of IC 200. The material 202 may be a semiconductor substrate, and may include a handle layer, a buried oxide (BOX) layer, an epitaxial layer, and/or other layers that may include any of a variety of electronic devices. The handle layer may be bulk silicon or other semiconductor or insulating material. The BOX layer, which may be omitted in some examples, may be a portion of a silicon-on-insulator (SOI) substrate. While the epitaxial layer in the illustrated example can be lightly doped p-type silicon (active silicon), the handle layer and epitaxial layer may be any other combinations of n-type or p-type material. In some examples, the material 202 can be a backside contact metal.

In block 104, a dielectric layer 204 is provided on the material 202. The dielectric layer 204 can be a layer of silicon dioxide in some examples of the integrated circuit 200.

In block 106, a first layer 302 is formed on the dielectric layer 204. First layer 302 can include a metal, such as aluminum or other metal, or a dielectric material, such as silicon dioxide. Advantageously, aluminum is widely available in semiconductor fabrication and can be used for first layer 302. FIG. 3 shows the first layer 302 on the dielectric layer 204. In a case where the first layer 302 is a metal layer, the first layer 302 may be deposited using physical vapor deposition (PVD) in some examples of the method 100.

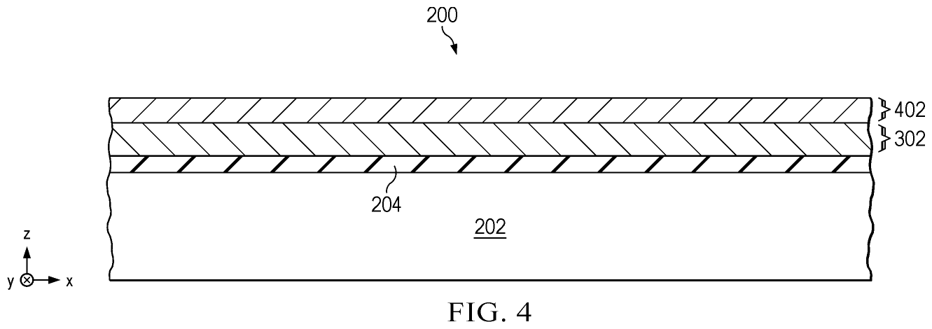

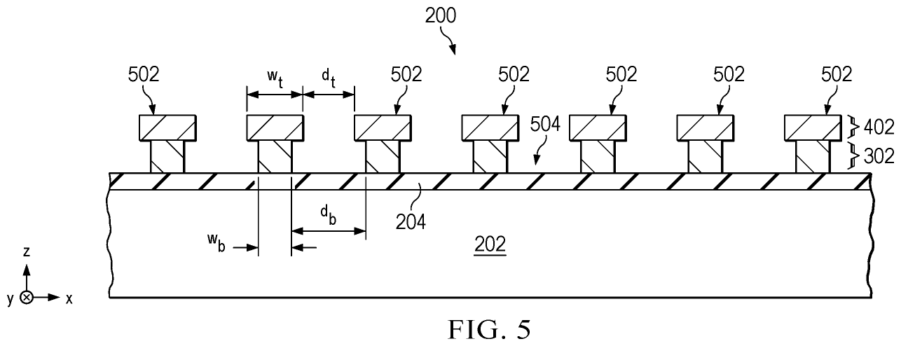

In block 108, a second layer 402 is formed on the first layer 302, so that the first layer 302 is between the second layer 402 and the dielectric layer 204. The second layer 402 may include a metal, such as nickel, cobalt, copper, palladium, ruthenium, platinum, or binary alloys thereof, or another metal in various examples of the integrated circuit 200. FIG. 4 shows the second layer 402 on the first layer 302. The second layer 402 can be deposited using PVD in some examples of the method 100. In some examples, both the second layer 402 and the first layer 302 can be formed as part of backend of line (BEOL) processing and can be as part of form interconnect structures on the material 202.

In block 110, the first layer 302 and the second layer 402 are patterned and etched to form protrusion structures that extend between the current terminals (e.g., source and drain) of a FET. FIG. 5 shows the protrusion structures 502 produced by etching the first layer 302 and the second layer 402. In the protrusion structures 502, the width of the second layer 402 can be greater than the width of the first layer 302, causing the protrusion structures 502 to have a mushroom or “T” shape, forming undercut grooves 504 between adjacent protrusion structures 502. For example, the patterned second layer 402 of a protrusion structure 502 can have a width Wₜ, the patterned first layer 302 of the protrusion structure 502 can have a width W_{b}, with Wₜ exceeding W_{b}. The patterned second layer of adjacent protrusion structures 502 can be spaced apart by a distance dₜ, and the first layer of adjacent protrusion structures can be spaced apart by a distance d_{b} which is greater than dₜ. The distance d_{b} can define the width of the undercut groove 504 and can also be greater than the width of patterned second layer Wₜ. As to be described below, the patterned second layer of 402 of the protrusion structures 502 can act as a guide and provide a sliding surface on which the carbon nanotubes can slide through the space between adjacent protrusion structures into the undercut groove below the second layer to form a film. Carbon nanotubes are to be deposited in the undercut grooves 504.

In some examples, the first layer 302 and the second layer 402 can be etched in different etch processes and using reactive ion etching. For example, the etching of the second layer can be performed using anisotropic etchant, such as a reactive ion etching process, using for example Cl₂/Ar chemicals. After the second layer 402 is patterned and the first layer is exposed, the exposed first layer 302 can be undercut using an isotropic etchant, or by an anisotropic etchant but with extended etching time, to create an undercut groove below the patterned second layer 402.

In some examples, the width Wₜ of a patterned second layer 402 of a protrusion structure 502, and the distance dₜ between the patterned second layer 402 of adjacent protrusion structure 502, can be the same and reflect a minimum line width of a lithography process used to pattern and etch the second layer 402. For example, in a case where the minimum line width of a lithography process used to pattern second layer 402 is 45 nanometers (nm), the width Wₜ and the distance dₜ can be at 45 nm. The distance d_{b} is larger than Wₜ and the width W_{b} of the patterned first layer 302. As to be explained below, such arrangements allow the alignment of the carbon nanotubes in the undercut grooves 504 to be set based on the width Wₜ (plus other factors, such as the length of the carbon nanotubes) while allowing more carbon nanotubes to be deposited in the widened undercut grooves 504.

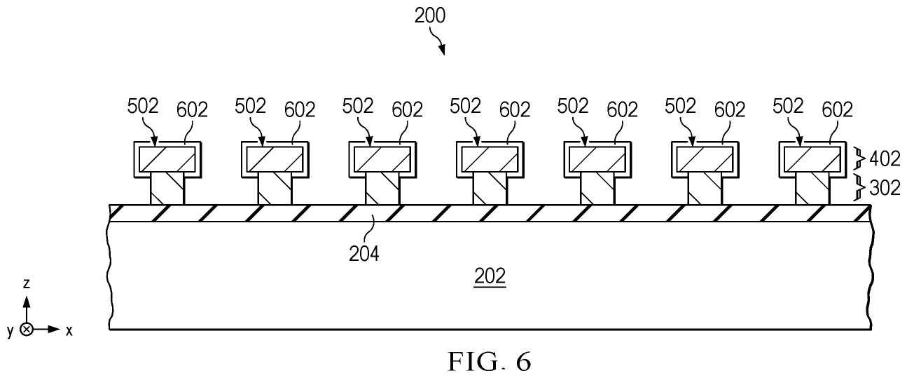

In block 112, a layer of graphitic carbon, such as graphene, is formed on at least some the surfaces of the second layer 402. The graphitic carbon may be deposited or grown on the surfaces of the second layer 402 using, for example, a plasma enhanced chemical vapor deposition process tuned to deposit graphitic carbon on the catalytic surfaces of the metal (e.g., Nickel, Cobalt) of the second layer 402 that enhance or facilitate the growth/deposition of graphitic carbon on the surface. The deposition/growth of graphitic carbon can be a relatively low temperature (e.g., at a BEOL temperature, such as about 300° Celsius), and the graphitic carbon thus deposited can be less than 1-2 nm thick. The graphitic carbon layer has a low adhesion to carbon nanotubes and can prevent the carbon nanotubes from adhering onto the surfaces of the second layer 402. FIG. 6 shows a layer of graphitic carbon 602 deposited on the surfaces of the second layer 402. As shown in FIG. 6, the thickness of the layer of graphitic carbon 602 can reduce the distance dₜ between the second layer 402 of adjacent protrusion structures 502. However, compared with other materials that have low adhesion to carbon nanotubes, such as methyl compounds or other hydrocarbon compounds, the thickness of the graphitic carbon layer can be relatively thin and well-controlled from the growth/deposition process. The formation of the thin graphitic carbon layer can be due to, for example, graphitic carbon being very non-reactive and can be grown by a thermal catalytic process or aided by a plasma at low temperatures, and a single layer or a small number of layers of graphitic carbon can be grown, depending on the material and thickness of the second layer 402. Accordingly, the distance dₜ between the second layer 402 of adjacent protrusion structures 502 can be well-controlled as well, and the distance dₜ can be substantially uniform across IC 200.

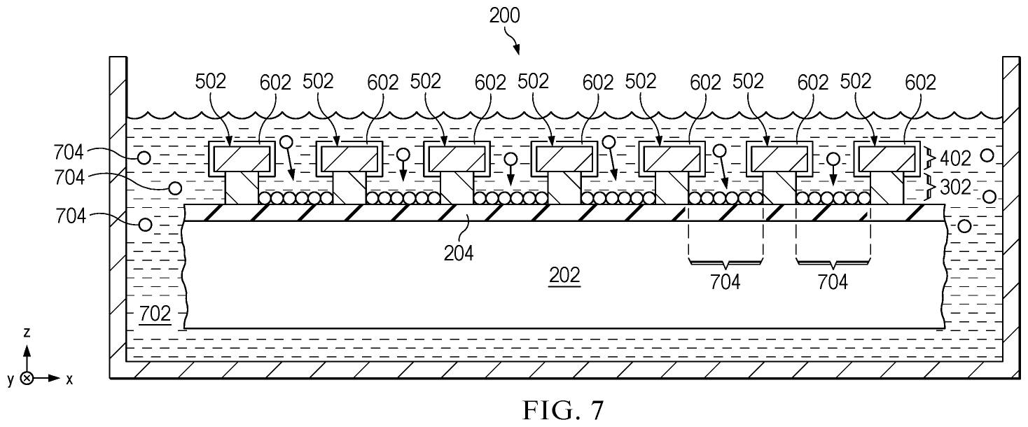

In block 114, carbon nanotubes are deposited in the space (the trenches) between the protrusion structures 502. FIG. 7 shows the integrated circuit 200 immersed in a solution 702 containing carbon nanotubes 704. Alternatively, the solution 702 may flow over the surface of the integrated circuit 200 along the longitudinal axis of the protrusion structures 502. The graphitic carbon 602 prevents the carbon nanotubes 704 from adhering to the surface of the second layer 402. The carbon nanotubes 704 may be coated with a polymer in some examples. The carbon nanotubes 704 are attracted to and settle on the dielectric layer 204 sliding off of the graphitic carbon 602 to settle into the undercut grooves 504 between the adjacent protrusion structures 502.

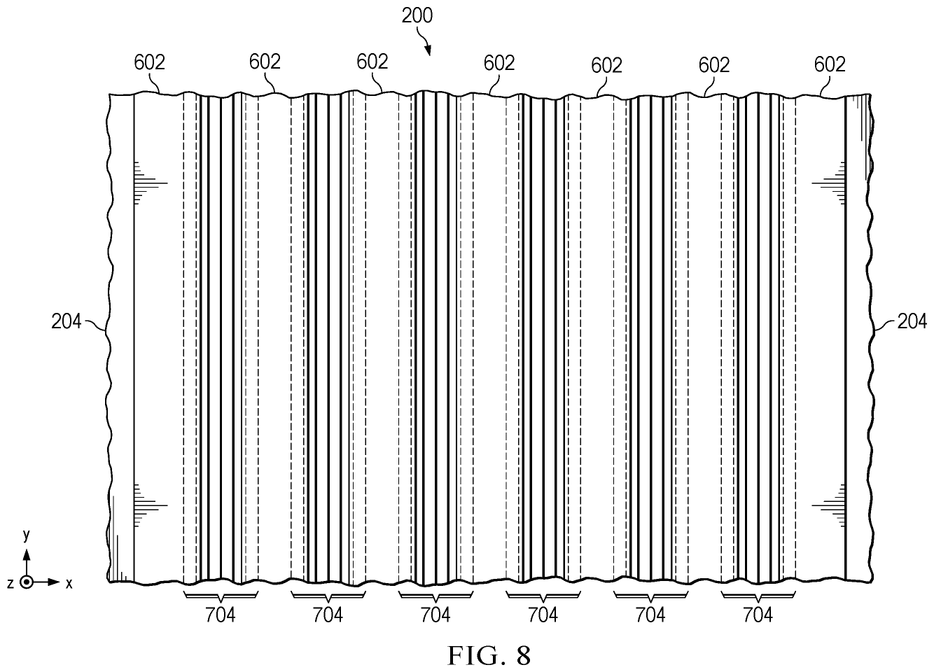

The alignment of the carbon nanotubes 704 with respect to a longitudinal axis of a FET (represented by the y-axis in FIG. 8) can be set by the shear rate as well as the distance dₜ between the second layer 402 of adjacent protrusion structures 502. By setting the distance dₜ to a minimum line width, and by coating the second layer with a graphitic carbon layer having a well-controlled thickness, the distance dₜ between the second layer 402 of adjacent protrusion structures 502 can be minimized and can be substantially uniform across the protrusion structures. Such arrangements can maximize (or at least increase/improve) the alignment of the carbon nanotubes in the FET.

Also, each of the undercut grooves 504 has a width defined by the distance d_{b} between first layer 302 of adjacent protrusion structures 502, which can be larger than dₜ. Compared with a case where no undercut groove is formed and the groove width d_{b} is the same as the distance dₜ, the formation of the undercut grooves 504 allow more carbon nanotubes to be deposited between adjacent protrusion structures while improving (or at least maintaining) the alignment of the carbon nanotubes. The angle of the carbon nanotubes 704 with respect to the protrusion structures 502 can be near zero degrees, with the maximum angle dependent on the length of the shortest carbon nanotubes 704 and the distance dₜ.

In some examples of the method 100, the integrated circuit 200 can be immersed in the solution 702 multiple times to further increase the number of the carbon nanotubes 704 deposited between the protrusion structures 502. Other techniques of depositing the carbon nanotubes 704 may be used in some examples of the method 100.

FIG. 8 is a top view of the integrated circuit 200 with the carbon nanotubes 704 deposited on the dielectric layer 204 between the protrusion structures 502. The width of an array of the carbon nanotubes 704 (or a film of carbon nanotubes) provided between the protrusion structures 502 can be defined by the distance d_{b} between the first layer 302 of adjacent protrusion structures 502. The spacing between adjacent array/films of the carbon nanotubes 704 can be defined by the width W_{b} of the first layer 302 of a protrusion structure 502. In a case of 50% undercut and both width Wₜ and distance dₜ are the same as the minimum line width, the width of an array of the carbon nanotubes 704 can be twice of the minimum line width, and the spacing between adjacent array/films of the carbon nanotubes 704 can be half of the minimum line width.

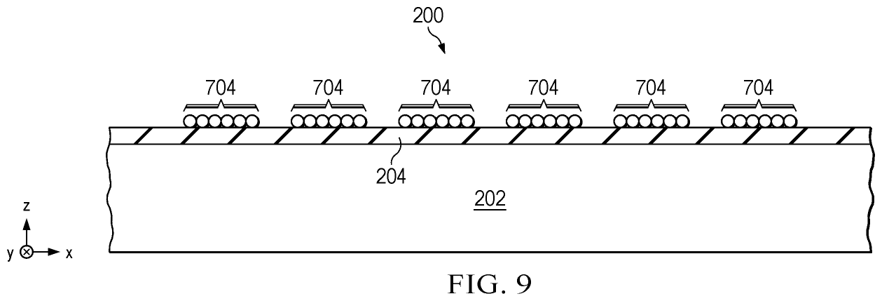

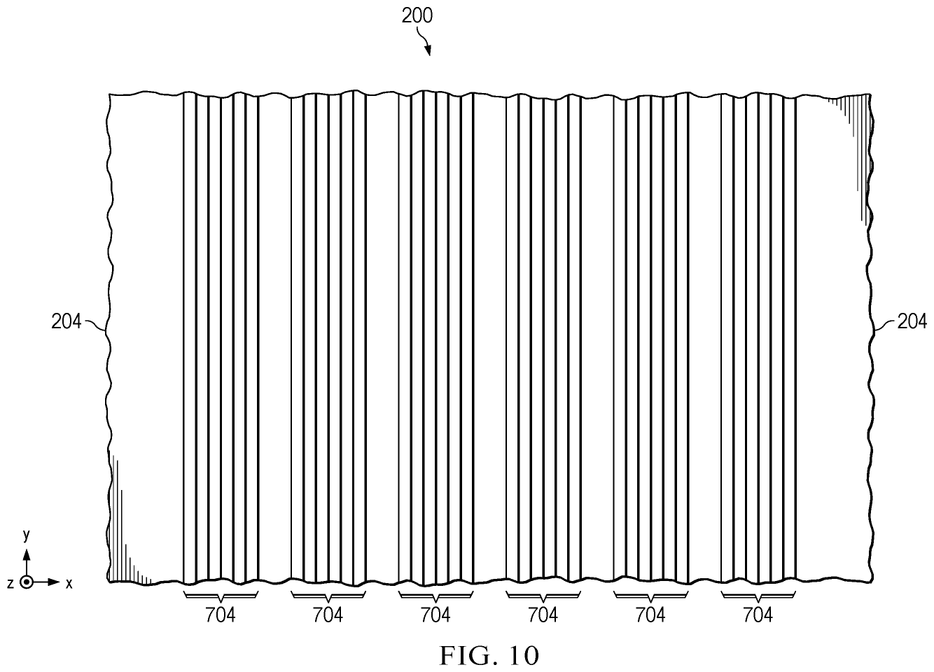

In block 116, the protrusion structures 502 are removed from the integrated circuit 200. The removal of the protrusion structures 502 can include initial removal of the graphitic carbon 602 or opening of etch pathways in the graphitic carbon 602 using an oxidizing agent such as, ozone, H₂O₂, or HNO₃ to etch the grain boundaries of the graphitic carbon 602. Ammonium persulfate, (NH₄)₂S₂O₈, can be used to etch the first layer 302 and the second layer 402 through the grain boundaries while rotating the integrated circuit 200, followed by washing of the reaction products. (NH₄)₂S₂O₈ does not etch the carbon nanotubes 704. FIGS. 9 and 10 show the integrated circuit 200 following removal of the protrusion structures 502. The carbon nanotubes 704 remain on the surface of the integrated circuit 200.

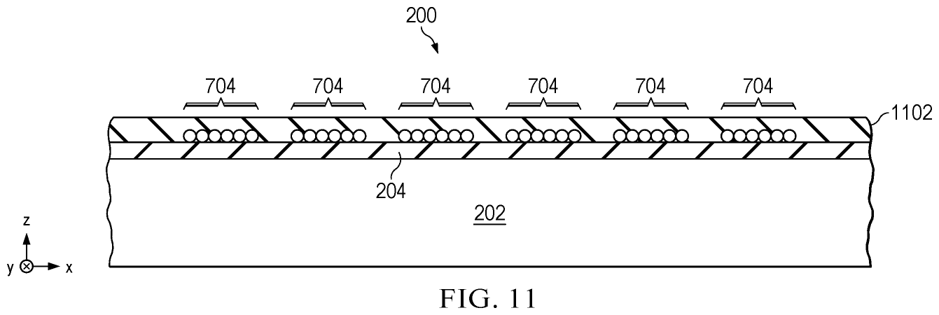

In block 118, a layer of insulation material (a dielectric layer, such as a silicon dioxide layer) is provided on the carbon nanotubes 704. FIG. 11 shows a dielectric layer 1102 provided on the carbon nanotubes 704.

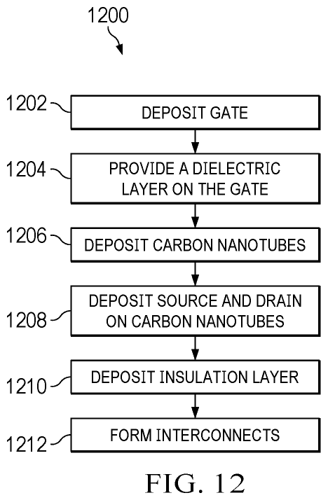

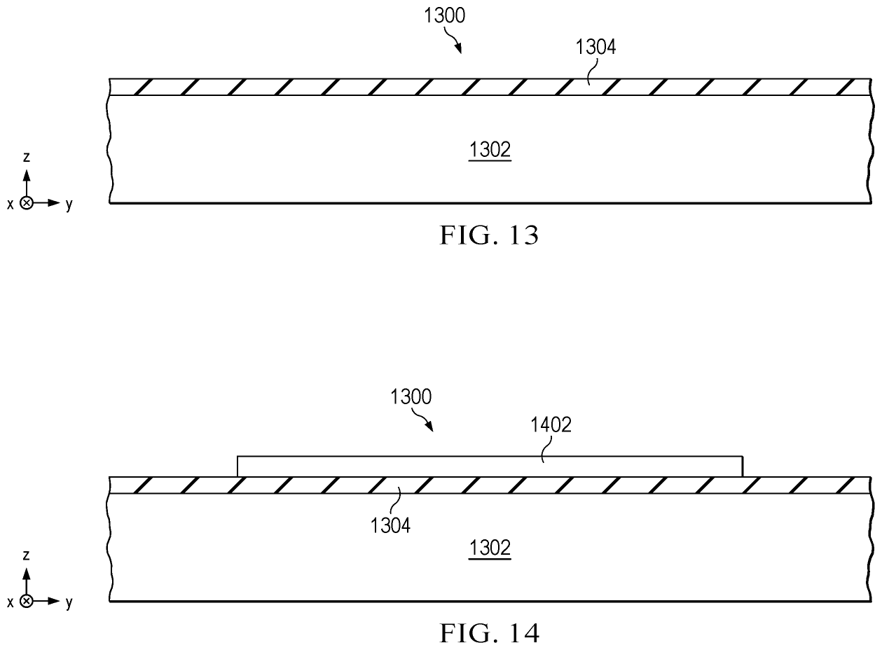

FIG. 12 is a flow diagram for an example method 1200 of fabricating a transistor with carbon nanotubes deposited using the method 100. Though depicted sequentially as a matter of convenience, at least some of the actions shown can be performed in a different order and/or performed in parallel. Additionally, some implementations may perform only some of the actions shown. FIGS. 13-18 illustrate examples of various operations of the method 1200. FIG. 13 shows an example integrated circuit 1300 including a semiconductor substrate 1302 and an insulation layer 1304 (e.g., a layer of silicon dioxide on the semiconductor substrate 1302).

In block 1202, a gate 1402 is formed on the insulation layer 1304. FIG. 14 shows the gate 1402 disposed on the insulation layer 1304. Formation of the gate 1402 can include depositing a layer of metal or polysilicon on the insulation layer 1304, and etching the layer to form the gate 1402.

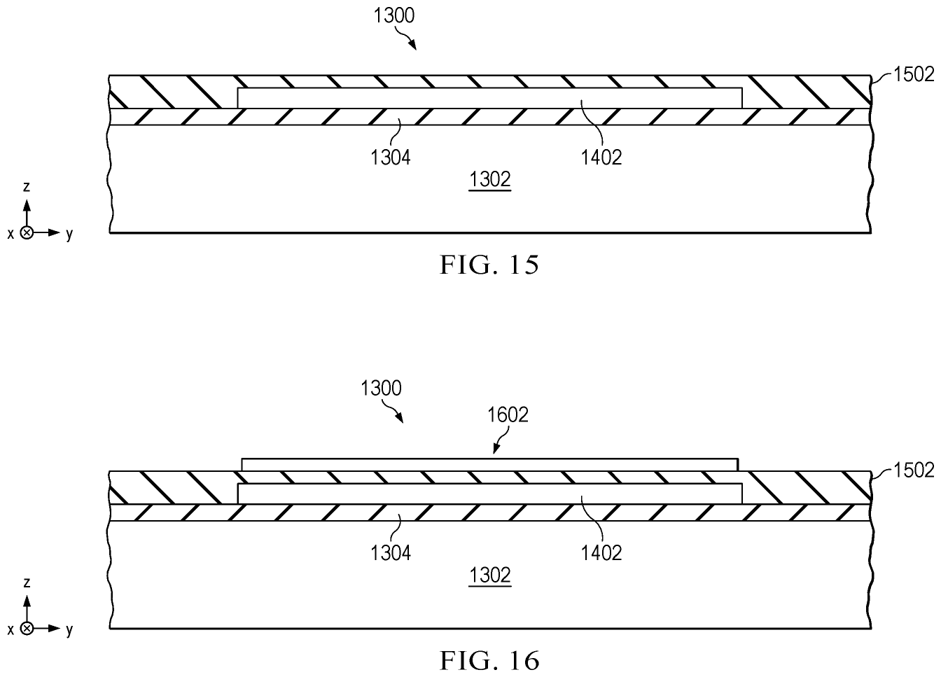

In block 1204, a dielectric layer is provided over the gate 1402. FIG. 15 shows the dielectric layer 1502 provided over the gate 1402. The dielectric layer 1502 can be hafnium dioxide, silicon dioxide or other dielectric material in examples of the integrated circuit 1300.

In block 1206, carbon nanotubes are deposited on the dielectric layer 1502. The carbon nanotubes can be deposited according to the method 100 to provide arrays of carbon nanotubes aligned in a selected direction, where the width of an array of carbon nanotubes is greater than a space separating adjacent arrays of carbon nanotubes. FIG. 16 shows carbon nanotubes 1602 deposited on the dielectric layer 1502 above the gate 1402.

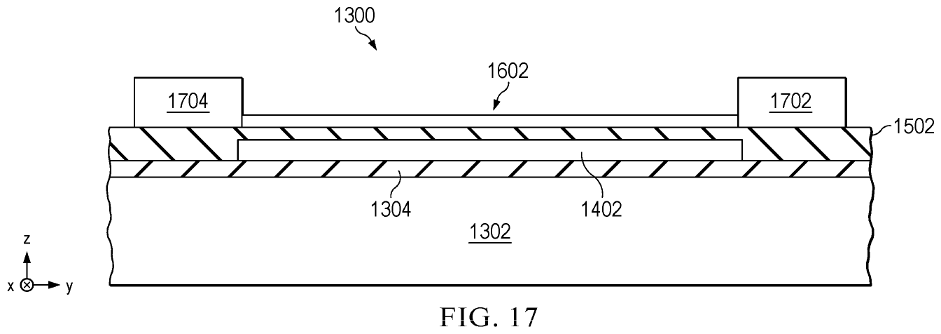

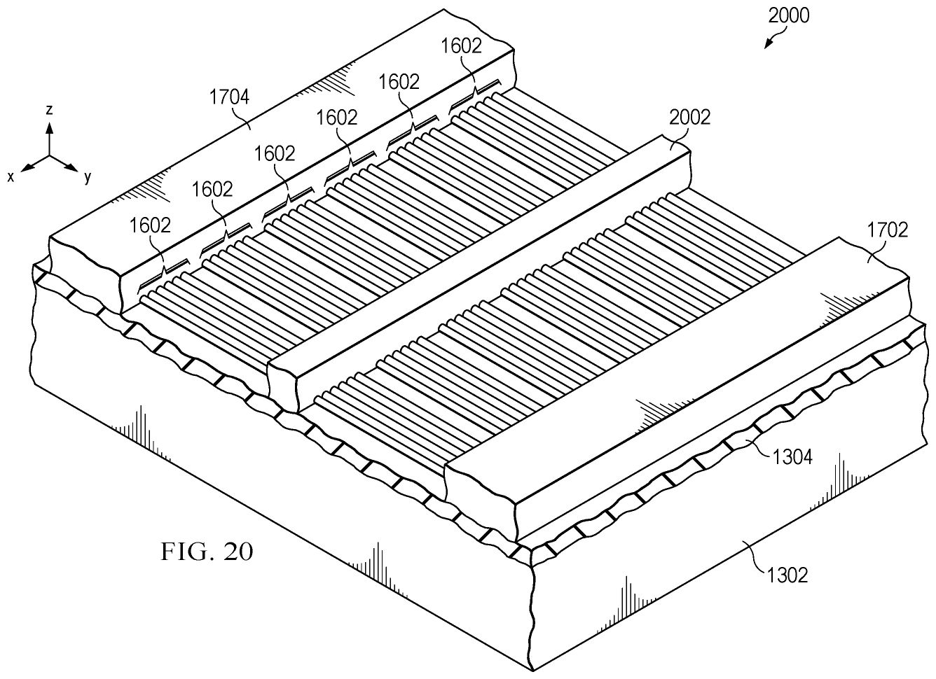

In block 1208, a source and a drain are formed on the carbon nanotubes 1602. FIG. 17 shows a source 1702 and a drain 1704 formed on the carbon nanotubes 1602 and the dielectric layer 1502. The source 1702 and the drain 1704 may be formed by depositing a layer of metal, such as palladium for p-type devices or low work function metal such as scandium and yttrium for n-type devices on the carbon nanotubes 1602 and the dielectric layer 1502 and etching the metal to form the source 1702 and the drain 1704. FIG. 19 shows a perspective view of the transistor including the source 1702, the drain 1704, the carbon nanotubes 1602, the dielectric layer 1502, and the gate 1402.

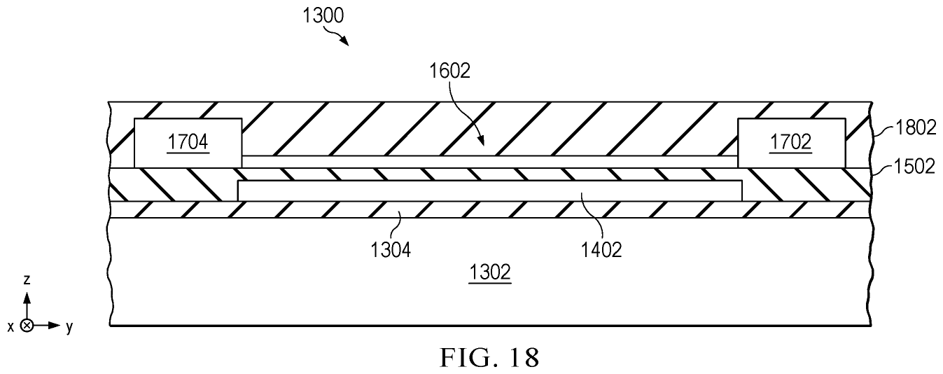

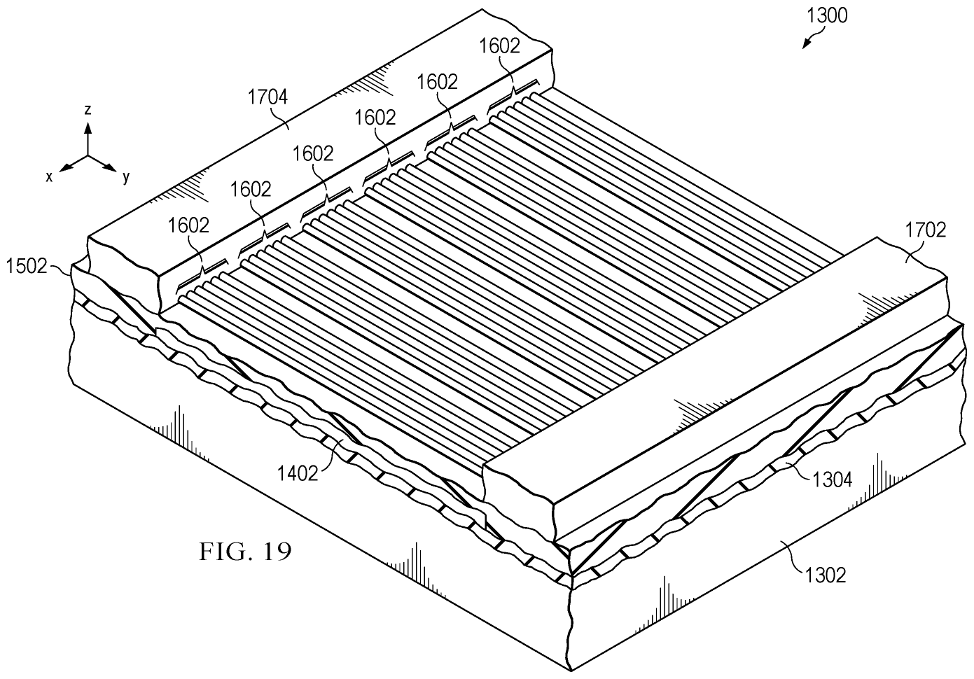

In block 1210, an insulation layer is provided over the source 1702, the drain 1704, and the carbon nanotubes 1602. FIG. 18 shows an insulation layer 1802 provided over the source 1702, the drain 1704, and the carbon nanotubes 1602. The insulation layer 1802 can be hafnium dioxide, silicon dioxide or other dielectric material.

FIG. 19 is a perspective view of an example of the integrated circuit 1300 fabricated according to the method 1200.

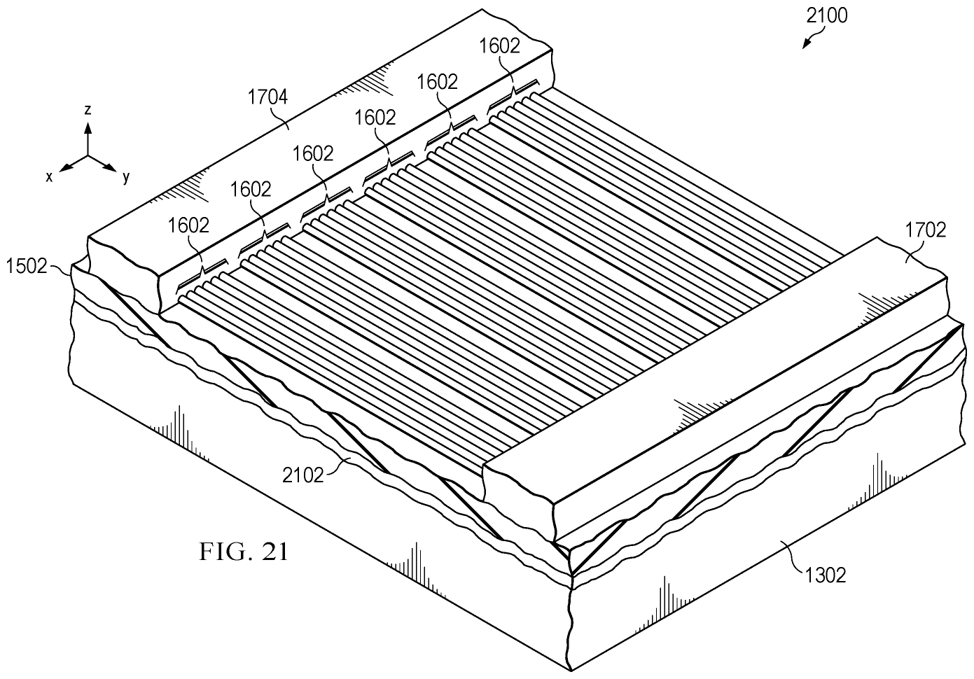

FIG. 20 is a perspective view of a transistor fabricated on an integrated circuit 2000. The transistor of FIG. 20 is similar to the transistor of FIG. 19, but includes a top gate 2002 rather than the bottom gate 1402. The method 1200 can include operations to produce a carbon nanotube based transistor with a bottom gate and/or a top gate.

FIG. 21 is a perspective view of a transistor fabricated on an integrated circuit 2100. The transistor of FIG. 21 is similar to the transistor of FIG. 19, but includes a global bottom gate 2102 rather than the local bottom gate 1402. The method 1200 can include operations to produce a carbon nanotube based transistor with a local or global bottom gate and/or a top gate.

In addition to transistors, carbon nanotubes arranged as described herein can be used in a wide variety of other applications. For example, carbon nanotubes arranged as described herein can be used in sensor devices (e.g., pressure, temperature, gas sensors, etc.), photonic devices (e.g., photonic sources, photonic detectors, etc.), and other devices.

While the use of particular transistors are described herein, other transistors (or other devices such as photonic devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs), or even over dielectric substrates.

Circuits described herein are reconfigurable to include additional or different components to provide functionality at least partially similar to functionality available prior to the component replacement.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

What is claimed is:

1. A method comprising:
forming, on a dielectric layer of an integrated circuit, a first layer of a first material;
forming, on the first layer, a second layer of a second material;
patterning the second layer to expose the first layer;
via the patterned second layer, etching the exposed first layer to form protrusion structures of the first layer and the second layer and undercut grooves between adjacent ones of the protrusion structures, in which the first layer of each protrusion structure has a first width, the second layer of each protrusion structure has a second width, and the second width is greater than the first width; and
depositing carbon nanotubes into the undercut grooves between the adjacent ones of the protrusion structures.

2. The method of claim 1, further comprising forming a graphitic carbon layer on the patterned second layer and before depositing the carbon nanotubes.

3. The method of claim 1, further comprising removing the protrusion structures after depositing the carbon nanotubes.

4. The method of claim 1, further comprising forming a dielectric layer on the carbon nanotubes.

5. The method of claim 1, further comprising longitudinally aligning the carbon nanotubes with the protrusion structures.

6. The method of claim 1, wherein the first material includes aluminum or a dielectric material.

7. The method of claim 1, wherein the second material includes at least one of: nickel, cobalt, copper, palladium, ruthenium, platinum, or binary alloys thereof.

8. The method of claim 1, wherein the first width is less than a minimum line width of the patterned second layer.

9. A method comprising:
forming, on a dielectric layer of an integrated circuit, a first layer of a first material;
forming, on the first layer, a second layer of a second material;
patterning the second layer to expose the first layer;
via the patterned second layer, etching the exposed second layer to form protrusion structures of the first layer and the second layer and grooves between adjacent ones of the protrusion structures; and
forming a graphitic carbon layer on at least part of the second layer of the protrusion structures; and
depositing carbon nanotubes into the grooves between the adjacent ones of the protrusion structures.

10. The method of claim 9, wherein the first layer of each protrusion structure has a first width, the second layer of each protrusion structure has a second width, and the second width is greater than the first width.

11. The method of claim 10, wherein the first width is less than a minimum line width.

12. The method of claim 9, further comprising removing the protrusion structures after depositing the carbon nanotubes.

13. The method of claim 9, further comprising forming a dielectric layer on the carbon nanotubes.

14. The method of claim 9, further comprising longitudinally aligning the carbon nanotubes with the protrusion structures.

15. The method of claim 9, wherein the first material includes aluminum or a dielectric material.

16. The method of claim 9, wherein the second material includes at least one of: nickel, cobalt, copper, palladium, ruthenium, platinum, or binary alloys thereof.

17. A transistor comprising:
a source and a drain;
a first array of carbon nanotubes having a first width, a first end connected to the source, and a second end connected to the drain; and
a second array of carbon nanotubes adjacent to and spaced apart from the first array of carbon nanotubes by a first spacing;
wherein the first width is greater than the first spacing.

18. The transistor of claim 17, wherein the first width is at least twice the first spacing.

19. The transistor of claim 17, further comprising a gate disposed beneath the first array of carbon nanotubes.

20. The transistor of claim 17, further comprising an insulation layer over the first and second arrays of carbon nanotubes.
